(19) United States
(12) Patent Application Publication
(10) Pub. No.: US 2013/0230651 A1
(43) Pub. Date: Sep. 5, 2013

(54) FILM FORMATION APPARATUS AND FILM FORMATION METHOD USING THE SAME

(71) Applicant: SANYO ELECTRIC CO., LTD., Osaka (JP)

(72) Inventor: Motohide Kai, Osaka (JP)

(73) Assignee: Sanyo Electric Co., Ltd., Osaka (JP)

(21) Appl. No.: 13/867,183

(22) Filed: Apr. 22, 2013

Related U.S. Application Data
(63) Continuation of application No. PCT/JP2011/074535, filed on Oct. 25, 2011.

(30) Foreign Application Priority Data
Oct. 27, 2010 (JP) 2010-241091

(51) Int. Cl. C23C 16/52

(52) U.S. Cl. CPC C23C 16/52
USPC 427/248.1; 118/708

(57) ABSTRACT

A film formation apparatus includes a processing chamber configured to keep an inside thereof in a decompressed state, a gas introduction path configured to introduce a predetermined source gas into the processing chamber, a catalyst provided inside the processing chamber in such a way that the source gas introduced through the gas introduction path comes into contact with a surface of the catalyst or passes near the surface thereof, a power supply unit configured to apply energy to the catalyst to heat the catalyst, a detector provided below the catalyst, and a controller configured to detect an electric current flowing through the detector or a voltage from the detector and to judge a contact state between the catalyst and the detector.

### CROSS REFERENCE TO RELATED APPLICATIONS

This application is a continuation application of International Application No. PCT/JP2011/074535, filed on Oct. 25, 2011, entitled “FILM FORMATION APPARATUS AND FILM FORMATION METHOD USING THE SAME”, which claims priority based on Article 8 of Patent Cooperation Treaty from prior Japanese Patent Applications No. 2010-241091, filed on Oct. 27, 2010, the entire contents of which are incorporated herein by reference.

### BACKGROUND OF THE INVENTION

1. Field of the Invention

This disclosure relates to a film formation apparatus to form a certain thin film on a surface of a substrate by means of the reaction of a source gas, and a film formation method using the same. In particular, this disclosure relates to a Cat-CVD apparatus capable of detecting abnormal deformation of a catalyst wire.

2. Description of the Related Art

Heretofore, apparatuses employing a chemical vapor deposition method (also referred to as a CVD method) have been used for forming an amorphous silicon (a-Si) film or a polycrystalline silicon (poly-Si) film. In particular, a plasma CVD (PCVD) method using plasma is known as a method delivering high throughput and is now in the mainstream of thin film formation methods. The PCVD method is a method of forming a film by generating plasma with application of high-frequency power under a gas pressure of approximately 1 to 10 Pa and depositing a product generated in the plasma on a substrate. In the meantime, a film formation method without plasma has been developed recently. This is a method in which a catalyst kept at a certain high temperature is placed in a processing chamber and a film is formed by the action of the catalyst. Such a method is called a catalytic CVD (Cat-CVD) method (see Japanese Patent Application Publication NO. 2009-108417, for example).

The Cat-CVD method is expected as a method with low-temperature processing since this method achieves film formation at a sufficiently-high deposition rate even on a substrate with a lower temperature than in common thermal CVD methods. In addition, the Cat-CVD method is free from a problem of substrate damage due to plasma because this method does not use plasma. Further, by changing the type of a gas introduced, the Cat-CVD method is applicable not only to formation of a Si-based film but also to formation of a diamond thin film and a protection film for electronic devices, for example. A configuration of a conventional film formation apparatus carrying out such a Cat-CVD method is described with reference to FIG. 5. FIG. 5 is a schematic view showing the configuration of the conventional film formation apparatus carrying out the Cat-CVD method.

The apparatus shown in FIG. 5 includes: processing chamber 100 capable of keeping the inside in a decompressed state with an exhaust system (not illustrated); substrate holder 102 configured to hold a substrate at a predetermined position in processing chamber 100; a gas introduction path (not illustrated) configured to introduce a certain source gas into processing chamber 100; catalyst 141 provided inside processing chamber 100; and power supply unit 105 configured to apply energy to catalyst 141 to keep catalyst 141 at a certain high temperature. Catalyst 141 is provided at a position where a source gas introduced through the gas introduction path comes into contact with a surface of catalyst 141 or passes near the surface of catalyst 141.

Catalyst 141 is formed of a single wire made of high-melting-point metal such as tungsten. As shown in FIG. 5, catalyst 141 is folded into a U-shape, and attached by being supported at two points in an upper portion of processing chamber 100. Power supply unit 105 is a DC or AC power supply, and causes catalyst 141 to generate heat by supplying an electric current to catalyst 141.

In the apparatus shown in FIG. 5, power supply unit 105 causes catalyst 141 to generate heat at a high temperature within a range of approximately 1500° C. to 2200° C. In this state, a certain source gas is introduced into processing chamber 100 through the gas introduction path. The gas thus introduced reacts with catalyst 141 when coming into contact with the surface of catalyst 141 or passing near the surface thereof. A product generated by this reaction arrives at the surface of the substrate held by substrate holder 102, thereby forming a certain thin film on the surface of the substrate.

In the Cat-CVD method described above, a film is formed by causing a product, which is generated from a source gas when the gas comes into contact with a surface of a catalyst or passes near the surface thereof, to arrive at a substrate. For this reason, a distance between the catalyst and the substrate is a very important parameter.

However, because the single wire is folded in the U-shape and supported at the two points in the conventional Cat-CVD apparatus as described above, the wire is sometimes deformed abnormally by being stretched out and coming into contact with the bottom surface of the chamber as the total time of applying the current increases. Specifically, catalyst 141 formed of the wire creeps with heat generation. Creeping catalyst 141 is stretched downward as shown by the broken line in FIG. 5 and comes into contact with the bottom surface of processing chamber 100.

Such deformation makes variations in factors such as the distance between catalyst 141 and the substrate, and consequently makes variations in the probability of arrival of the product and the substrate temperature rise due to radiation heat. This causes variations in the deposition rate and film quality. In addition, since the level of deformation is difficult to control, the deformation is also problematic in terms of the reproducibility of the film formation processing under the condition that catalyst 141 is deformed.

Further, the level of deformation of catalyst 141 cannot be visually checked from the outside of processing chamber 100. Accordingly, in a conventional practice, processing chamber 100 needs to be opened to the air in order to visually check this deformation level. However, the opening of processing chamber 100 to the air causes contamination and reduction of an apparatus operation rate.

### SUMMARY OF THE INVENTION

An embodiment of the invention provides a configuration of a film formation apparatus carrying out the Cat-CVD method, which reduces the problems due to the deformation of a catalyst and is excellent in running cost and productivity.

A first aspect of the invention is a film formation apparatus that includes: a processing chamber capable keeping an inside thereof in a decompressed state; a gas introduction path configured to introduce a certain source gas into the processing chamber; a catalyst provided inside the processing chamber in such a way that the source gas introduced through the gas introduction path comes into contact with a surface of the catalyst or passes near the surface thereof; a power supply unit configured to apply energy to the catalyst to heat the catalyst; a detector provided below the catalyst; and a controller configured to detect an electric current flowing through the detector or a voltage from the detector and to judge a contact state between the catalyst and the detector.

A second aspect of the invention is a film formation method using a film formation apparatus, the film formation apparatus including: a processing chamber capable keeping an inside thereof in a decompressed state; a gas introduction path configured to introduce a certain source gas into the processing chamber; a catalyst provided inside the processing chamber in such a way that the source gas introduced through the gas introduction path comes into contact with a surface of the catalyst or passes near the surface thereof; a power supply unit configured to apply energy to the catalyst to heat the catalyst; a detector provided below the catalyst; and a controller configured to detect an electric current flowing through the detector or a voltage from the detector and to judge a contact state between the catalyst and the detector. The film formation method includes: introducing the source gas and thereby forming a film on a front surface of a substrate provided opposed to the catalyst, until the controller judges that the catalyst and the detector contact each other; and stopping the introduction of the source gas when the controller judges that the catalyst and the detector contact each other.

According to the aspect(s) of the invention, a process anomaly due to abnormal deformation of the catalyst wire can be detected without visual check from the outside of the processing chamber.

### BRIEF DESCRIPTION OF THE DRAWINGS

FIG. 1 is a schematic front cross-sectional view of a film formation apparatus according to a first embodiment of the invention.

FIG. 2 is a schematic perspective view showing the relationship between a catalyst and substrate holders of the film formation apparatus according to the first embodiment of the invention.

FIG. 3 is a detailed magnified view of the schematic perspective view of FIG. 1 explaining the configuration of the catalyst.

FIG. 4 is a schematic view showing the film formation apparatus according to the first embodiment of the invention in which a catalyst wire is stretched out.

FIG. 5 is a schematic view showing a configuration of a conventional film formation apparatus.

### DESCRIPTION OF THE PREFERRED EMBODIMENT

An embodiment of the invention is described in detail with reference to the drawings. Note that the same or equivalent parts in the drawings are given the same reference numerals and are not described again for avoiding duplicate description.

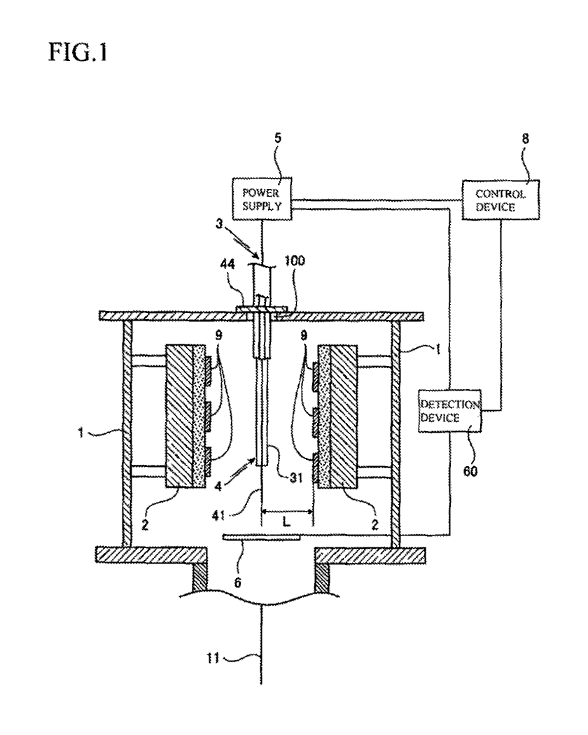

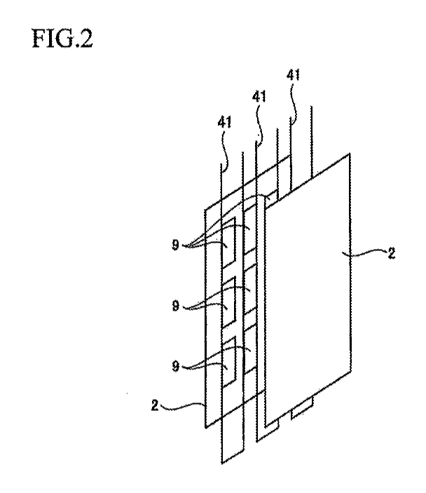

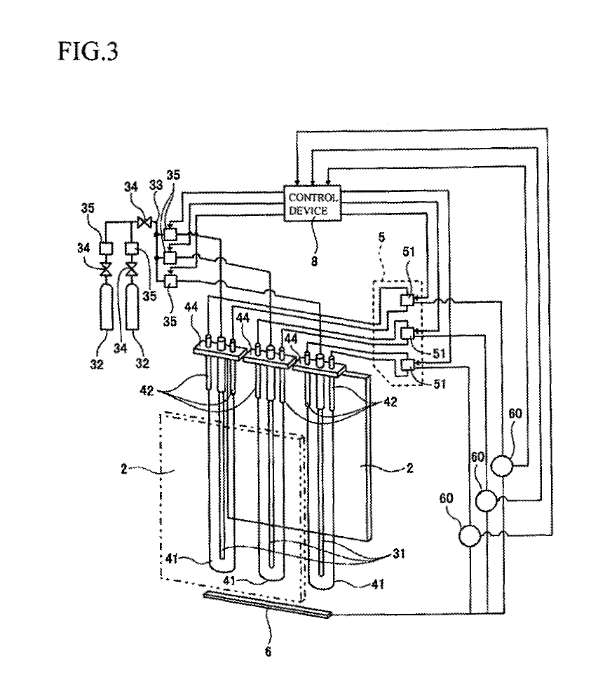

FIG. 1 is a schematic front cross-sectional view of a film formation apparatus according to a first embodiment of the invention. FIG. 2 is a schematic perspective view showing the relationship between a catalyst and substrate holders of the film formation apparatus according to the first embodiment. FIG. 3 is a schematic perspective view explaining the configuration of the catalyst.

The apparatus shown in FIG. 1 includes: processing chamber 1 capable of keeping the inside in a decompressed state with exhaust system 11; substrate holders 2 configured to hold substrates 9 at predetermined positions in processing chamber 1; gas introduction path 3 configured to introduce a certain source gas into processing chamber 1; catalyst 4 provided inside processing chamber 1 in such a way that a source gas introduced through gas introduction path 3 comes into contact with a surface of catalyst 4 or passes near the surface of catalyst 4; and power supply unit 5 configured to apply energy to catalyst 4 to heat catalyst 4 to a certain temperature.

Processing chamber 1 is an air-tight vacuum container having a gate valve (not illustrated). Exhaust system 11 includes multi-stage vacuum pumps such as a combination of a turbo-molecular pump and a rotary pump, and is configured to be capable of exhausting the air inside processing chamber 1.

As shown in FIGS. 1 and 2, substrate holders 2 hold substrates 9 in a state extending perpendicular to the bottom surface of processing chamber 1. Each substrate holder 2 has a configuration capable of holding substrates 9 on its substrate holding surface while keeping substrates 9 at postures extending perpendicular to the bottom surface. Each substrate holder 2 also has a configuration capable of holding multiple substrates 9 inside processing chamber 1 at the same time. Two substrate holders 2 are arranged to be symmetric to each other with respect to a plane in which catalyst 4 and gas introduction heads 31 are provided, and each substrate holder is capable of holding multiple substrates 9. Although not illustrated, the film formation apparatus may be provided with a substrate temperature control mechanism configured to control the temperature of substrates 9 to keep substrates 9 at a certain temperature.

As shown in FIGS. 1 and 2, in the apparatus of the first embodiment, catalyst 4 includes multiple catalyst wires 41 each having a shape extending in a plane perpendicular to the bottom surface of processing chamber 1 and parallel to the processing surfaces of substrates 9 being hold on substrate holders 2. Each catalyst wire 41 is made of high-melting-point metal such as tungsten, molybdenum, or tantalum. As can be understood from the schematic perspective view of FIG. 3, each catalyst wire 41 has a configuration where a single wire is shaped in the form of a long letter U. Accordingly, the two ends of the wire are located on the upper side and a bent portion thereof is located on the lower side. Here, the diameter of the wire is approximately 0.2 mm to 3 mm.

The two ends of each catalyst wire 41 located on the upper side are connected to introduction holders 42. Introduction holders 42 are each in the form of a wire or a rod slightly thicker than each catalyst wire 41, and made of high-melting-point metal which is the same as or similar to that of each catalyst wire 41.

Note that, as described above, the distance between substrates 9 and catalyst 4 (shown by the letter L in FIG. 1) is preferably approximately 1 cm to 20 cm for the purpose of enabling a sufficient amount of product to arrive at substrates 9 while reducing the amount of radiation heat from catalyst 4. Setting the distance between substrates 9 and catalyst 4 smaller than 1 cm causes a problem where the amount of radiation heat on substrates 9 is too large. By contrast, setting the distance between substrates 9 and catalyst 4 larger than 20 cm causes a problem where the amount of product arriving at substrates 9 is reduced.

Meanwhile, as shown in FIGS. 1 and 3, processing chamber 1 is provided with holder plates 44 respectively holding the pairs of introduction holders 42. The pairs of introduction holders 42 respectively penetrate holder plates 44 in an air-tight manner with high-melting-point insulating members (not illustrated), such as alumina, interposed therebetween. Holder plates 44 are preferably made of a high-melting-point material such as alumina or PBN (Pyrolytic Boron Nitride). Holder plates 44 are attached to the outer surface of an upper wall portion of processing chamber 1. Specifically, as shown in FIG. 1, openings 100 each smaller than holder plate 44 are formed corresponding to the number of holder plates 44. The pairs of introduction holders 42 held by respective holder plates 44 extend downward with being inserted through openings 100 and are respectively connected to catalyst wires 41 at their lower ends.

A vacuum seal (not illustrated) is provided between each holder plate 44 and the outer surface of the upper wall portion of processing chamber 1, whereby holder plate 44 seals opening 100 in an air-tight manner. Here, holder plates 44 are fastened to the upper wall portion of processing chamber 1 by screws, for example. If the heating of processing chamber 1 through holder plates 44 is problematic, a heat-insulating member is provided between each holder plate 44 and processing chamber 1.

As shown in FIG. 3, power supply unit 5 includes current-applying power supplies 51 the number of which is equal to that of catalyst wires 41. Current-applying power supplies 51 are configured to carry an alternate or direct current to catalyst wires 41 and thereby heat catalyst wires 41 to a certain temperature high enough to resolve a source gas (to a high temperature of approximately 2200° C., for example). Each current-applying power supply 51 is connected to control device 8. Control device 8 controls current-applying power supplies 51 to control electric currents to respective catalyst wires 41 independently. Thereby, the temperatures of catalyst wires 41 are controlled independently.

Note that making the number of current-applying power supplies 51 equal to the number of catalyst wires 41 is not an essential condition. For example, the apparatus may have a configuration such that multiple catalyst wires 41 are connected in parallel and control elements (such as variable resistors) capable of controlling the respective circuits are provided to the circuits. In this case, the number of current-applying power supplies 51 is smaller than the number of catalyst wires 41 (for example, one).

As shown in FIG. 1 or FIG. 3, gas introduction path 3 includes: gas introduction heads 31 provided inside processing chamber 1; piping 33 connecting gas cylinders 32 provided outside processing chamber 1 to gas introduction heads 31; valves 34, mass flow controllers 35, and filters (not illustrated) provided on piping 33; and the like. As shown in FIG. 3, the number of gas introduction heads 31 provided is equal to the number of catalyst wires 41.

As shown in FIG. 3, each gas introduction head 31 is an elongated pipe kept perpendicular to the bottom surface of processing chamber 1. Each gas introduction head 31 is located between two linear portions of corresponding U-shaped catalyst wire 41. In other words, gas introduction heads 31 are provided on the same plane as the plane of catalyst wires 41 perpendicular to the bottom surface. Accordingly, as in the case of catalyst wires 41, gas introduction heads 31 are parallel to substrates 9 held by substrate holders 2. Here, gas introduction heads 31 are made of high-melting-point metal, quartz, or the like.

Gas introduction heads 31 have equally-spaced gas outlet holes (not illustrated) in their lateral surfaces opposed to substrates 9. As shown in FIG. 3, piping 33 of gas introduction path 3 branches into the number of gas introduction heads 31. Gas introduction head 31 is connected to the end of each branch. Mass flow controllers 35 are provided to the branches of piping 33 respectively. Control device 8 is capable of controlling mass flow controllers 35 independently. In this embodiment, flow rates of a source gas to be introduced into processing chamber 1 through respective gas introduction heads 31 can be controlled independently. Note that, in this specification, a “source gas” is a collective term of gases to be introduced for film formation, and includes not only a gas contributing directly to film formation but also gases not directly related to film formation such as a carrier gas and a buffer gas.

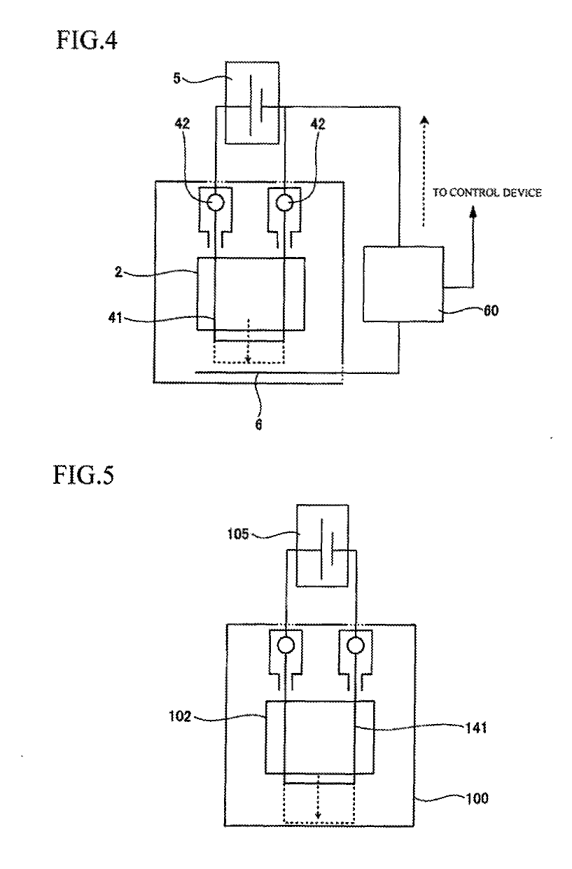

In this embodiment, as shown in FIG. 1, metal plate 6 as a sensor or a detector which is insulated from processing chamber 1 is disposed below catalyst wires 41. This metal plate 6 is electrically connected to power supply unit 5. As shown in FIG. 4, if any of catalyst wires 41 is stretched out and comes into contact with metal plate 6, metal plate 6 and power supply unit 5 are brought into conduction. Conduction between catalyst wire 41 and metal plate 6 makes an electric current flowing through metal plate 6 changed when power supply unit 5 is a constant-voltage power supply, or makes a voltage (power) output from metal plate 6 changed when power supply unit 5 is a constant-current power supply. This change is detected by detection device 60, and the detection result is sent to control device 8. If the detection result is out of a certain range, control device 8 judges that catalyst wire 41 is stretched out and deformed too much to carry out a normal film formation operation, and thus controls to halt the film formation operation. For example, the introduction of the resource gas through gas introduction path 3 is stopped. Alternatively, the output from power supply unit 5 is stopped. In this way, when any of catalyst wires 41 comes into contact with metal plate 6, it is possible to correctly judge that catalyst wire 41 is deformed on the basis of the detection result from detection device 60. This makes it possible to replace catalyst wires 41 in accordance with the judgment result from control device 8 and to elongate the lifetime of catalyst wires 41 before replacement. As a result, frequent replacement of catalyst wires 41 can be avoided.

When an insulator film is formed, it is preferable to dispose metal plate 6 outside a film formation area to prevent the film from being deposited on metal plate 6.

An operation of the film formation apparatus of this embodiment having the above configuration is described below. Substrate holders 2 holding multiple substrates 9 thereon are carried in processing chamber 1.

After the gate valve of processing chamber 1 is closed, gas introduction path 3 is activated to introduce the source gas into processing chamber 1 at a certain flow rate. To put it differently, the source gas blows out through the gas outlet holes of gas introduction heads 31 and is diffused in a space inside processing chamber 1. In this event, control device 8 controls mass flow controllers 35 on gas introduction path 3 so that the amounts of source gas to be introduced through gas introduction heads 31 are controlled independently. Meanwhile, an exhaust rate regulator provided in exhaust system 11 of processing chamber 1 controls the exhaust rate so that the inside of processing chamber 1 is kept at a certain vacuum pressure.

Then, catalyst wires 41 constituting catalyst 4 are turned on by current-applying power supplies 51 of power supply unit 5 and raise the temperature of catalyst wires 41 to a certain temperature high enough to resolve the source gas. The source gas blown out through gas introduction heads 31 and diffused causes a reaction when coming into contact with the surfaces of catalyst wires 41 or passing near the surfaces thereof. A product generated by this reaction arrives at the surfaces of substrates 9, and the product thus arriving at substrates 9 is deposited on substrates 9. Thereby, a thin film is formed on substrates 9.

When the thin film of a certain thickness is formed by keeping the above state for a certain period, the operations of gas introduction path 3 and power supply unit 5 are stopped. After that, exhaust system 11 exhausts the air inside processing chamber 1 again and then an inert gas is introduced into processing chamber 1 so that processing chamber 1 is brought to atmospheric pressure. After processing chamber 1 is brought to atmospheric pressure, the gate valve is opened and substrates 9 are taken out from processing chamber 1.

As the film formation operation is repeated, catalyst wires 41 are deformed and stretched downward as shown in FIG. 4. Metal plate 6 and detection device 60 provided in this embodiment enables control device 8 to judge if catalyst wires 41 are deformed and to perform control to stop the film formation operation when judging based on the judgment result that the normal film formation operation cannot be carried out. Specifically, control device 8 stops the operations of gas introduction path 3 and power supply unit 5. Thereby, wasteful consumption of the source gas can be suppressed.

A specific example of film formation is described by taking a case of forming an a-Si film as an example. A mixture of monosilane at a flow rate of 10 to 500 sccm and a hydrogen gas at a flow rate of 20 to 1000 sccm is introduced as a source gas. When vapor deposition is carried out while the temperature of catalyst 4 is kept at 1500 to 2200° C. and the pressure inside processing chamber 1 is kept at 0.1 to 10 Pa, an a-Si film can be formed at a deposition rate of approximately 30 to 250 angstroms/min. Such an a-Si film can be effectively used as a solar cell and the like.

Note that, when catalyst wire 41 is a U-shaped wire, it is also conceivable that the apparatus has a configuration where a current introduction unit is attached to the two ends of catalyst wire 41 facing downward and a bent portion of catalyst wire 41 facing upward is hooked by a hook or the like. In this case, however, because the lower side of the wire is fixed, the wire expands in a horizontal direction due to thermal expansion, which changes a distance between catalyst wire 41 and substrates 9. For this reason, it is preferable that catalyst wire 41 have a configuration of being disposed with the two ends thereof facing upward. Incidentally, catalyst wire 41 may have a shape other than a U shape, including a rounded w-shape or a rounded m-shape wherein two U-shaped form are laterally connected with each other.

In addition, although an a-Si film is employed in the above example, the apparatus of the first embodiment is usable for formation of a thin film of any type including a silicon nitride film, a polysilicon film, and the like. Further, a wafer used for manufacturing a semiconductor device, a liquid crystal substrate used for manufacturing a liquid crystal display, and the like may be employed as substrate 9 on which a film is to be formed. If substrate 9 is a large-area substrate, substrate 9 may be carried in processing chamber 1 directly without using substrate holder 2.

It should be understood that the embodiments disclosed herein are exemplary in all points and do not limit the invention. The scope of the invention is defined not by the description of the embodiment described above but by claims, and it is intended that the scope of the invention includes equivalents of claims and all modifications within the scope of claims.

For example, although metal plate 6 is used as the detector in the above embodiment, the detector may be made of a conductive material other than metal. Moreover, the detector may have a shape other than a plate shape, including one with a mesh pattern.

### EXPLANATION OF REFERENCE NUMERALS

1 processing chamber
11 exhaust system
2 substrate holder
3 gas introduction path
31 gas introduction head
35 mass flow controllers
4 catalyst
41 catalyst wire
5 power supply unit
51 current-applying supply
6 metal plate (detector)
8 control device
9 substrate

What is claimed is:

1. A film formation apparatus comprising:
a processing chamber configured to keep an inside thereof in a decompressed state;
a gas introduction path configured to introduce a source gas into the processing chamber;
a catalyst provided inside the processing chamber such that the source gas introduced through the gas introduction path comes into contact with a surface of the catalyst or passes near the surface thereof;
a power supply unit configured to apply energy to the catalyst to heat the catalyst;
a detector provided below the catalyst; and
a controller configured to detect an electric current flowing through the detector or a voltage from the detector and to judge a contact state between the catalyst and the detector.

2. The film formation apparatus according to claim 1, wherein the detector is disposed outside a film formation area.

3. The film formation apparatus according to claim 1, wherein the controller is configured to determine that the catalyst and the detector contact each other when the electric current flowing through the detector or the voltage from the detector is out of a certain range.

4. The film formation apparatus according to claim 3, wherein the controller is configured to stop the introduction of the source gas through the gas introduction path when judging that the catalyst and the detector contact each other.

5. A film formation method using a film formation apparatus, the film formation apparatus including: a processing chamber capable keeping an inside thereof in a decompressed state; a gas introduction path configured to introduce a predetermined source gas into the processing chamber; a catalyst provided inside the processing chamber in such a way that the source gas introduced through the gas introduction path comes into contact with a surface of the catalyst or passes near the surface thereof; a power supply unit configured to apply energy to the catalyst to heat the catalyst; a detector provided below the catalyst; and a controller configured to detect an electric current flowing through the detector or a voltage from the detector and to judge a contact state between the catalyst and the detector, the film formation method comprising:
introducing the source gas and thereby forming a film on a surface of a substrate provided opposed to the catalyst, until the controller judges that the catalyst and the detector contact each other; and
stopping the introduction of the source gas when the controller judges that the catalyst and the detector contact each other.

6. A film formation method comprising:
introducing a source gas into a decompressed processing chamber such that the introduced source gas passed near or comes in contact with a catalyst provided in the decompressed processing camber while heating the catalyst, thereby forming a film on a surface of a substrate provided opposed to the catalyst
detecting whether a deformation of the catalyst over time excess a threshold by detecting whether the catalyst contacts a sensor provided below the catalyst.

7. The film formation method of claim 6, wherein
the detecting step comprises detecting a value of an electric current flowing through the sensor or a voltage of the sensor.

8. The film formation method of claim 6, further comprising:
stopping the introduction of the source gas when it is determined that the catalyst contacts the sensor.

9. The film formation method of claim 6, further comprising:
stopping the heating of the catalyst when it is determined that the catalyst contacts the sensor.
